(19) United States
(12) Patent Application Publication
(10) Pub. No.: US 2025/0365925 A1
(43) Pub. Date: Nov. 27, 2025

(54) Memory Circuitry And Methods Used In Forming Memory Circuitry

(71) Applicant: Micron Technology, Inc., Boise, ID (US)

(72) Inventors: Yuanzhi Ma, Meridian, ID (US); Si-Woo Lee, Saratoga, CA (US); Scott E. Sills, Boise, ID (US)

(73) Assignee: Micron Technology, Inc., Boise, ID (US)

(21) Appl. No.: 19/189,568

(22) Filed: Apr. 25, 2025

Related U.S. Application Data
(60) Provisional application No. 63/650,286, filed on May 21, 2024.

(51) Int. Cl. H10B 12/00

(52) U.S. Cl. CPC H10B 12/30; H10B 12/03; H10B 12/05

(57) ABSTRACT

Memory circuitry comprises vertically-stacked memory cells individually comprising a horizontal transistor and a capacitor electrically coupled therewith. Such are horizontally spaced relative one another along an axis. The capacitor comprises a storage-node electrode, a common electrode that is common to a plurality of the capacitors of the memory cells, and a capacitor insulator between the storage-node and common electrodes. In a vertical cross-section that is horizontally-elongated orthogonal to the axis, the storage-node electrode comprises a radially-inner portion that is spaced from a radially-outer portion at least by the capacitor insulator and the common electrode. The radially-inner portion is of a diamond-like shape in the vertical cross-section. Other embodiments, including method, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory array region having horizontal tiers in which individual memory cells are received (e.g., arrayed in x and y directions). The stack in the 3D memory array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-10 and 59 are diagrammatic sectional views of constructions in accordance with embodiments of the invention.

FIGS. 11-58 are diagrammatic sequential sectional and/or enlarged views of the construction of FIGS. 3-10, or portions thereof or alternate and/or additional embodiments, in process in accordance with some embodiments of the invention.

### DETAILED DESCRIPTION OF EXAMPLE EMBODIMENTS

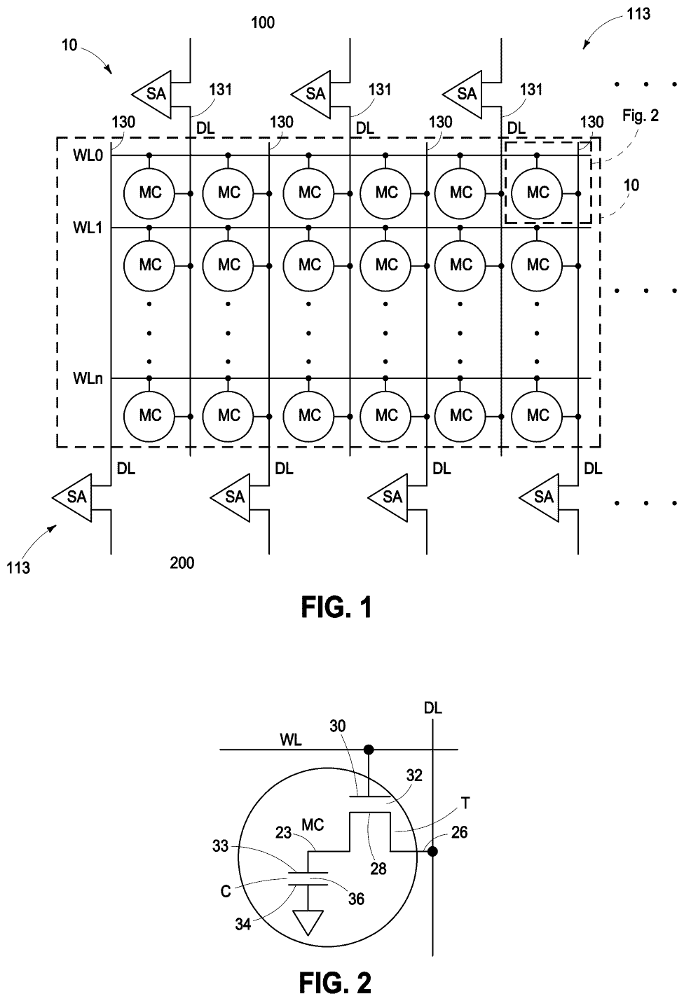

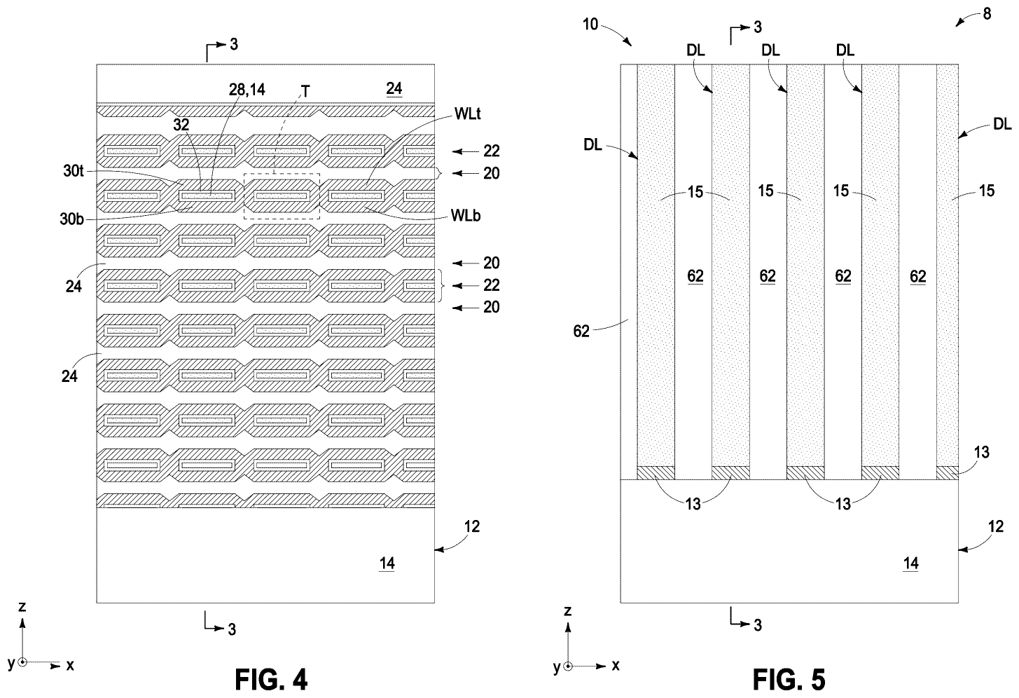

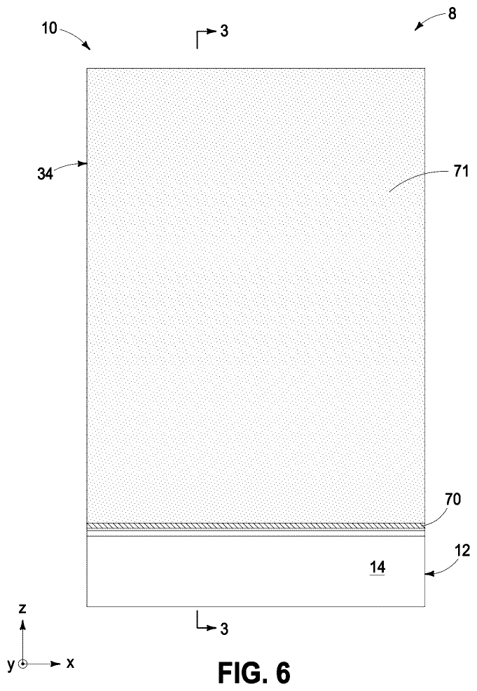

Embodiments of the invention encompass memory circuitry (e.g., DRAM) comprising vertically-stacked memory cells individually comprising a horizontal transistor and a capacitor electrically coupled therewith. Embodiments of the invention also encompass methods used in forming such memory circuitry. Example structure embodiments are first described with reference to FIGS. 1-10.

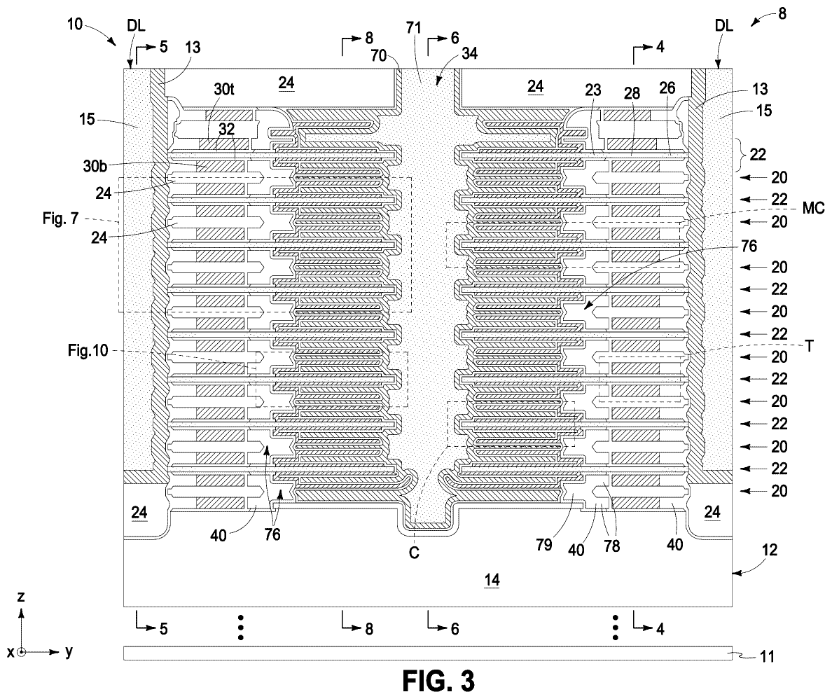

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part of) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Non-schematic structure embodiments as shown herein in FIGS. 3+have the wordlines/access lines running horizontally and the digitlines/sense lines running vertically. Further, and by way of example only, sense amps SA could be on only one side or all directly above or directly below memory array area 10.

Referring to FIG. 3-10, an example fragment of a substrate construction 8 comprising array or array area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-10-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array.

Example memory circuitry (e.g., that of or comprising construction 8) comprises vertically-alternating tiers 20, 22 (e.g., along example direction z) of insulative material 24 (e.g., silicon dioxide and/or silicon nitride) and vertically-stacked memory cells MC, respectively. Example construction 8 comprises a semiconductor substrate 12 (e.g., a bulk wafer comprising monocrystalline silicon 14) above which tiers 20 and 22 are received. Regardless, memory cells MC individually comprise a horizontal transistor T, for example comprising a first source/drain region 23, a second source/drain region 26, and a channel region 28 horizontally between the first and second source/drain regions. Regions 23, 26, and 28 of different immediately-horizontally-adjacent memory cells MC into and out of the plane of the page upon which FIG. 3 lies in a common memory-cell tier 22 may be isolated relative one another by insulative material (not shown). Transistor T also comprises a gate 30* (e.g., gate-all-around the channel; e.g., conductive metal material) having a gate insulator 32 (e.g., dielectric or ferroelectric) between at least channel region 28 and gate 30* (an * being used as a suffix to be inclusive of all such same-numerically-designated structures or portions thereof that may or may not have other suffixes). Gate 30* comprises part of a one of a plurality of horizontal conductive access lines WL* that individually directly electrically couple together multiple gates 30* of different ones of horizontal transistors T that are in the same memory-cell tier 22. An example insulator material 40 (e.g., silicon nitride) is laterally proximate lateral sides/edges of gates 30*. In one embodiment and as shown, gate 30* comprises part of a top gate 30t that is part of a top access line WLt and comprises part of a bottom gate 30b that is part of a bottom access line WLb.

Example capacitor C comprises a storage-node electrode 33, a common electrode 34 (e.g., comprising conductive metal material 70 and conductively-doped polysilicon 71) that is common (directly electrically coupled) to a plurality of capacitors C (at least some not necessarily all) of memory cells MC, and a capacitor insulator 36 there-between (e.g., dielectric or ferroelectric). Storage-node electrode 33 is directly coupled to first source/drain region 23 of transistor T. Digitlines DL (e.g., comprising conductive materials 13 and 15) extend through vertically-alternating tiers 20 and 22. Digitlines DL of different immediately-horizontally-adjacent memory cells MC into and out of the plane of the page upon which FIG. 3 lies in a common memory-cell tier 22 may be isolated relative one another by insulative material 62 (e.g., silicon dioxide and/or silicon nitride). Individual second source/drain regions 26 of individual transistors T that are in different memory-cell tiers 22 are directly electrically coupled to individual digitlines DL. Capacitor C and horizontal transistor T may be considered as being horizontally spaced relative one another along an axis 80 (i.e., a straight-line and that is not necessarily central relative to either but is as shown; e.g., along example direction y).

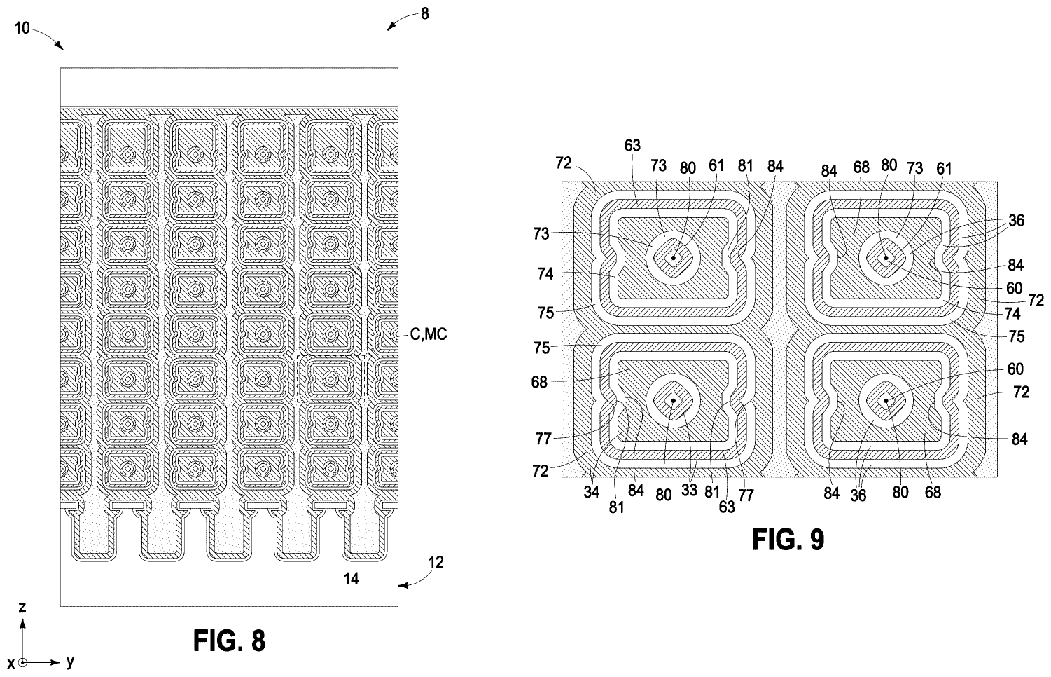

In one embodiment, capacitor storage-node electrode 33 comprises a mid-portion 60 on and about axis 80 (e.g., conductively-doped semiconductor material, such as conductively-doped monocrystalline or polycrystalline silicon). Storage-node electrode 33 comprises an inner annulus 61 directly electrically coupled with mid-portion 60, with inner annulus 61 being about (circumferentially around) mid-portion 60 in a vertical cross-section that is horizontally-elongated orthogonal to axis 80 (e.g., the vertical cross-section that is FIG. 8 or 9; e.g., along example direction x). In one embodiment and as shown, mid-portion 60 is of a diamond-like shape in such vertical cross-section. Storage-node electrode 33 comprises an outer annulus 63 directly electrically coupled with inner annulus 61, with outer annulus 63 being about inner annulus 61 in such vertical cross-section. In one embodiment, in such vertical cross-section, outer annulus 63 has a pair of laterally-opposing radial projections 81 that are individually horizontally aside and point radially inward toward mid-portion 60.

In one embodiment, mid-portion 60 comprises a conductive metal silicide 89 there-atop (e.g., shown as a thick, bold line; e.g., WSiₓ) and there-below and that are respectively directly against inner annulus 61 (and that may alternately be considered as portions thereof instead of part of mid-portion 60). In one such embodiment and as shown, conductive metal silicide 89 is laterally over and aside an end 66 of mid-portion 60.

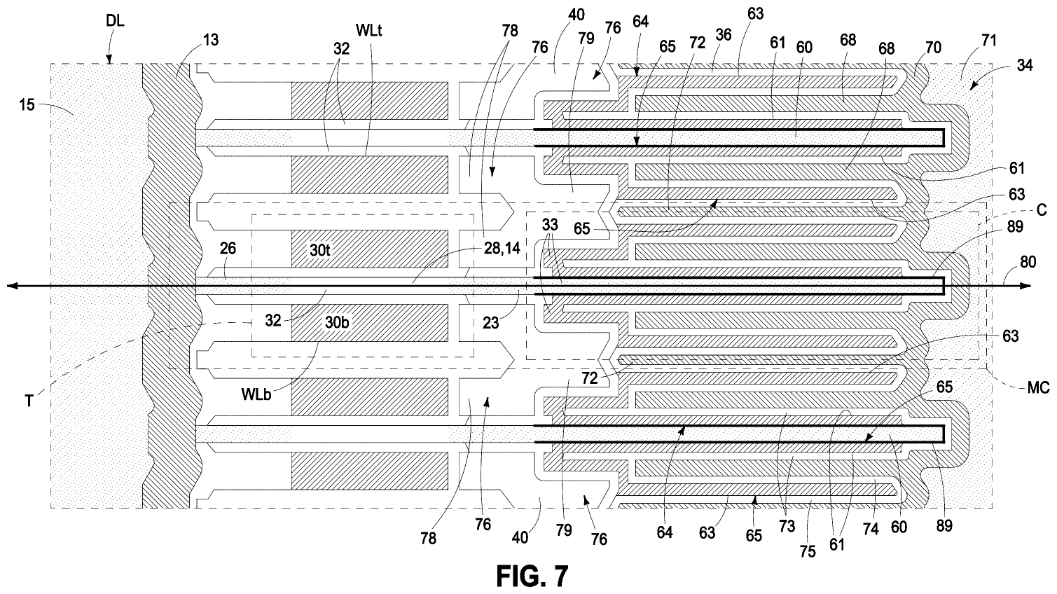

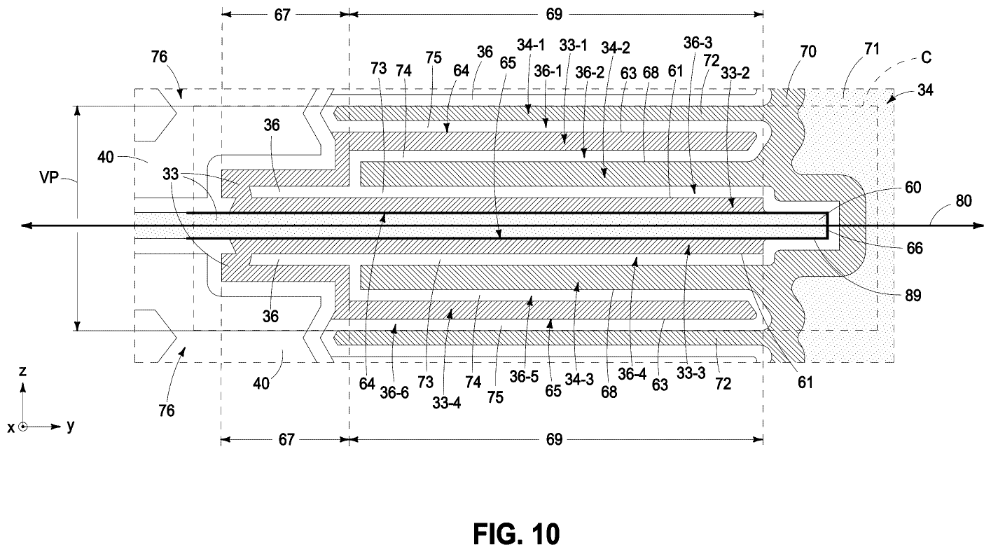

In one embodiment, capacitor storage-node electrode 33 comprises an upper sideways container 64 directly electrically coupled with and directly above mid-portion 60. Upper sideways container 64 faces horizontally away from horizontal transistor T in a vertical cross-section that is through and horizontally-elongated along axis 80 (e.g., the vertical cross-section that is FIG. 7 or 10). Capacitor storage-node electrode 33 comprises a lower sideways container 65 directly electrically coupled with and directly below mid-portion 60. Lower sideways container 65 faces horizontally away from horizontal transistor T in the vertical cross-section that is through and horizontally-elongated along axis 80. In one embodiment, inner and outer annuli 61 and 63, respectively, comprise part of each of upper and lower sideways containers 64 and 65, respectively. In the vertical cross-section that is through and horizontally-elongated along axis 80, and in one embodiment, each of upper and lower sideways containers 64 and 65 comprise a horizontally-elongated vertically-widest portion 69 and a horizontally-elongated vertically-narrowest portion 67 that are directly against mid-portion 60. In one embodiment, internal volume of each of horizontally-elongated vertically-narrowest portions 67 is completely filled with capacitor insulator 36.

In one embodiment, common electrode 34 in the vertical cross-section that is horizontally-elongated orthogonal to axis 80 comprises an inner ring 68 about inner annulus 61 and an outer portion 72 about inner ring 68. As used herein, “ring” and “annulus” are synonymous with one another and used collectively for distinguishing language in the claims. Such may be circular, non-circular, a combination of differently curved and/or different length segments, a combination of straight and/or different length segments, a combination of curved and straight segments, etc.

In one embodiment, capacitor insulator 36 in the vertical cross-section that is horizontally-elongated orthogonal to axis 80 comprises a first intervening ring 73 about inner annulus 61 between inner annulus 61 and inner ring 68. Capacitor insulator 36 comprises a second intervening ring 74 about inner ring 68 between inner ring 68 and outer annulus 63. Capacitor insulator 36 comprises a third intervening ring 75 about outer annuus 63 between outer annulus 63 and outer portion 72. Third intervening ring 75 comprises a pair of laterally-opposing radial projections 77 that are individually horizontally aside and point radially inward toward mid-portion 60 in the vertical cross-section that is horizontally-elongated orthogonal to axis 80. In one embodiment, in the vertical cross-section that is horizontally-elongated orthogonal to axis 80, second intervening ring 74 has a pair of laterally-opposing radial projections 84 that are individually horizontally aside and point radially inward toward mid-portion 60. In one embodiment, mid-portion 60 comprises a conductive metal silicide 89 there-atop and there-below and that are respectively directly against upper and lower sideways containers 64 and 65.

In one embodiment, memory circuitry 8 comprises an insulative structure 76 vertically between immediately-vertically-adjacent memory cells MC (i.e., there being no other memory cell that is vertically between those that are immediately-vertically-adjacent one another). Insulative structure 76 is of a sideways Y-like shape in the vertical cross-section that is through and horizontally-elongated along axis 80. In such vertical cross-section, insulative structure 76 comprises a horizontal stem 79 and a pair of vertically-spaced and parallel arms 78 that are contiguous with and project horizontally relative to horizontal stem 79. In one embodiment, in the vertical cross-section that is through and horizontally-elongated along axis 80, horizontal transistor T comprises a top gate 30t and a bottom gate 30b, with one of arms 78 being vertically aligned with bottom gate 30b of an upper of immediately-vertically-adjacent memory cells MC and the other of arms 78 being vertically aligned with top gate 30t of a lower of immediately-vertically-adjacent memory cells MC. In one embodiment, vertical thickness of horizontal stem 79 is greater than vertical thickness of each of arms 78.

Any other attribute(s) or aspect(s) as shown and/or described herein with respect to other embodiments may be used in the embodiments shown and described with reference to the above embodiments.

In one embodiment, memory circuitry (e.g., 8) comprises vertically-stacked memory cells (e.g., MC) individually comprising a horizontal transistor (e.g., T) and a capacitor (e.g., C) electrically coupled therewith. The capacitor and horizontal transistor are horizontally spaced relative one another along an axis (e.g., 80). An insulative structure (e.g., 76) is vertically between immediately-vertically-adjacent of the memory cells. The insulative structure is of a sideways Y-like shape in a vertical cross-section that is through and horizontally-elongated along the axis. In such vertical cross-section, the insulative structure comprises a horizontal stem (e.g., 79) and a pair of vertically-spaced and parallel arms (e.g., 78) that are contiguous with and project horizontally relative to the horizontal stem. Any other attribute(s) or aspect(s) as shown and/or described herein with respect to other embodiments may be used.

In one embodiment, memory circuitry (e.g., 8) comprises vertically-stacked memory cells (e.g., MC) individually comprising a horizontal transistor (e.g., T) and a capacitor (e.g., C) electrically coupled therewith. The capacitor and horizontal transistor are horizontally spaced relative one another along an axis (e.g., 80). The capacitor comprises a storage-node electrode (e.g., 33) and a common electrode (e.g., 34) that is common to a plurality of the capacitors of the memory cells. A capacitor insulator (e.g., 36) is between the storage-node and common electrodes. The storage-node electrode comprises a mid-portion (e.g., 60) on and about the axis. The storage-node electrode also comprises an upper sideways container (e.g., 64) directly electrically coupled with and directly above the mid-portion. The upper sideways container faces horizontally away from the horizontal transistor in a vertical cross-section that is through and horizontally-elongated along the axis. The storage-node electrode also comprises a lower sideways container (e.g., 65) directly electrically coupled with and directly below the mid-portion. The lower sideways container faces horizontally away from the horizontal transistor in such vertical cross-section. In such vertical cross-section, in one embodiment, each of the upper and lower sideways containers comprises a horizontally-elongated vertically-widest portion (e.g., 69) and a horizontally-elongated vertically-narrowest portion (e.g., 67) that are directly against the mid-portion. Any other attribute(s) or aspect(s) as shown and/or described herein with respect to other embodiments may be used.

In one embodiment, memory circuitry (e.g., 8) comprises vertically-stacked memory cells (e.g., MC) individually comprising a horizontal transistor (e.g., T) and a capacitor (e.g., C) electrically coupled therewith. The capacitor and horizontal transistor are horizontally spaced relative one another along an axis (e.g., 80). The capacitor comprises a storage-node electrode (e.g., 33) and a common electrode (e.g., 34) that is common to a plurality of the capacitors of the memory cells. A capacitor insulator (e.g., 36) is between the storage-node and common electrodes. In a vertical cross-section that is horizontally-elongated orthogonal to the axis, the storage-node electrode comprises a radially-inner portion (e.g., that of mid-portion 60) that is spaced from a radially-outer portion (e.g., that of outer annulus 63) at least by the capacitor insulator and the common electrode. The radially-inner portion is of a diamond-like shape in such vertical cross-section. In one such embodiment, a conductive metal-material annulus (e.g., that of inner-annulus 61) is about and directly against the radially-inner portion. Any other attribute(s) or aspect(s) as shown and/or described herein with respect to other embodiments may be used.

FIG. 10 shows capacitors C having a vertical pitch VP having three layers of common electrode 34-1, 34-2, and 34-3, six layers of capacitor insulator 36-1, 36-2, 36-3, 36-4, 36-5, and 36-6, and four layers of storage-node electrode 33-1, 33-2, 33-3, and 33-4 (in addition to mid-portion 60).

Any other attribute(s) or aspect(s) as shown and/or described herein with respect to other embodiments may be used in the embodiments shown and described with reference to the above embodiments.

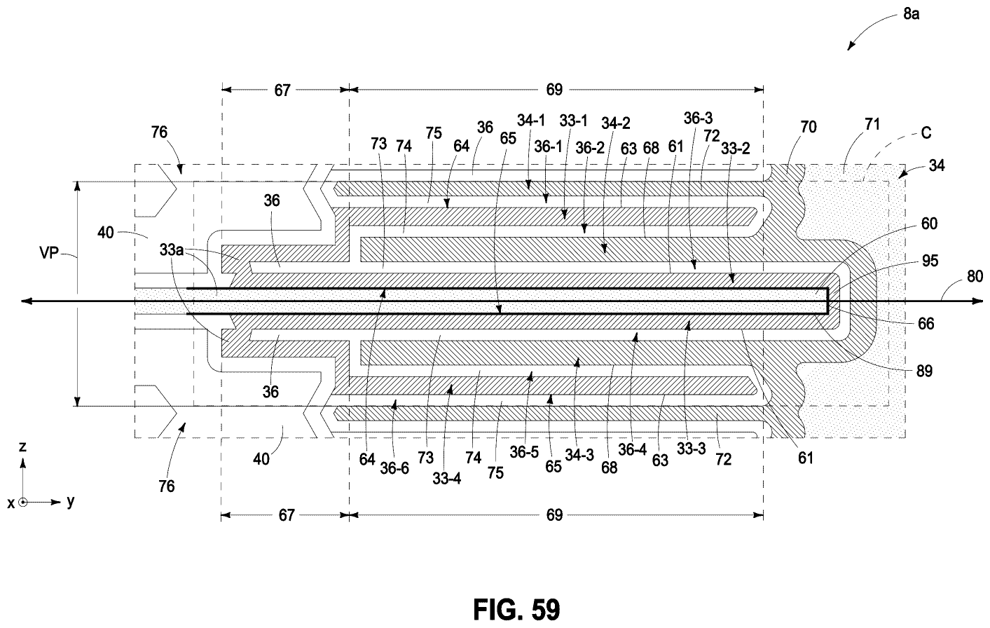

An alternate example embodiment and construction 8a is shown in FIG. 59. Like numerals from the above-described embodiments have been used where appropriate, with some construction differences being indicated with the suffix “a” or with different numerals. In example construction 8a, storage-node electrode 33acomprises a connecting portion 95 laterally over and aside end 66 in a vertical cross-section that is through and horizontally-elongated along axis 80 (e.g., that of FIG. 59), with connecting portion 95 being contiguous with inner annulus 61. Capacitor insulator 36 is laterally between connecting portion 95 and common electrode 34. Any other attribute(s) or aspect(s) as shown and/or described herein with respect to other embodiments may be used.

Embodiments of the invention encompass methods used in forming memory circuitry, by way of example only that incorporate device/structure as referred to above. Nevertheless, the method embodiments may incorporate, form, and/or have any of the attributes described with respect to device embodiments.

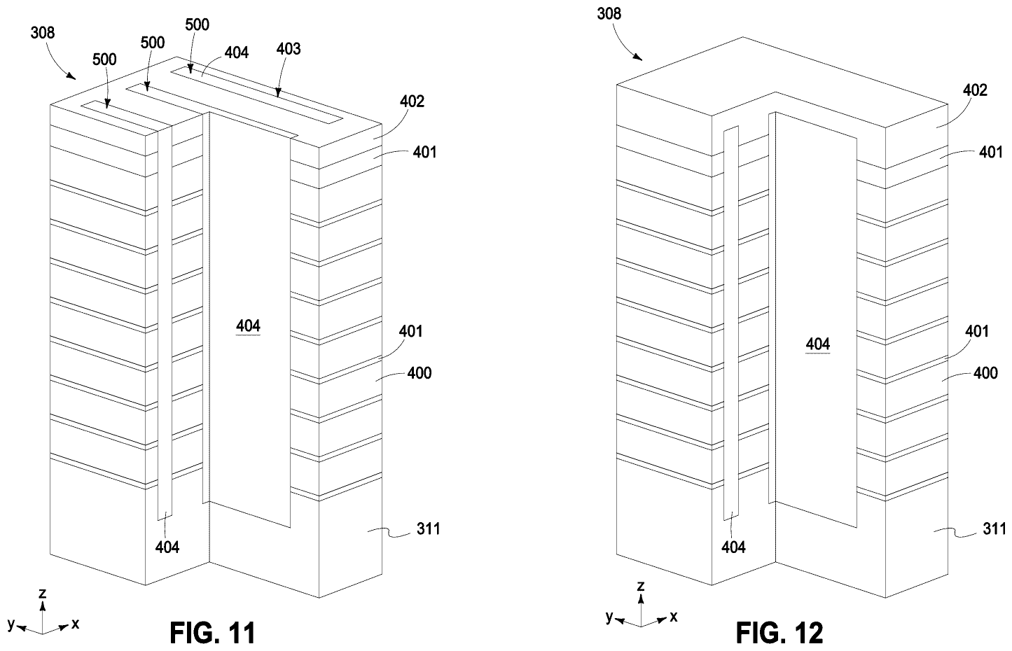

FIGS. 11-58 by way of example sequentially show predecessor constructions in an example method used in forming memory circuitry. Such memory circuitry ultimately comprises memory cells that individually comprise a horizontal transistor that is electrically coupled (e.g., directly) with a capacitor. Such memory circuitry may comprise structural embodiments of the invention as described above with respect to FIGS. 1-10 and 59.

FIGS. 11-58 show orientation relative to x, y, and z directions, with some aspects shown with cut planes (e.g., along xz-planes and along yz-planes) to show some embedded features. The artisan will recognize that operations illustrated in and described with reference to FIGS. 11-58 can be performed by manufacturing systems, such as a semiconductor fabrication systems, configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques for formation of the various shown features. For brevity, not all operations are described, such as those that would be recognized by the artisan as may being conducted where desired or necessary (e.g., some doping of semiconductor materials with conductivity enhancing dopants during and/or after deposition to achieve desired conductivity/semiconductivity, annealings, etc.). Further, some methods, techniques, processes, and operations may be performed in different orders, or at different times, or otherwise modified. Further, some operations may be omitted from the described fabrication operations, or other operations may be added to the described fabrication operations. Also, the artisan will appreciate that other materials and/or structures may be used than those specifically referred to below depending on application and whether such are temporary and/or remain in the finished construction, what is or is not being selectively etched relative to what, etc. with those provided below being examples only.

Referring to FIG. 11, construction 308 comprises a bulk monocrystalline silicon substrate 311 having a stack of vertically-alternating layers comprising silicon material 400 (e.g., elemental monocrystalline or polycrystalline silicon and which may include one or more additional elements) and silicon-germanium material 401 (e.g., Si₁₋ₓGeₓ and which may include one or more additional elements) formed there-above. Silicon-material layers 400 will comprise part of horizontal transistors and capacitors in a finished construction of the memory circuitry. A silicon oxycarbide hardmask material 402 has been formed there-atop. Trenches 403 horizontally-elongated in x have been formed, filled with carbon, and carbon 404 polished back to the top of hardmask material 402. Such may be considered as forming or comprising horizontally-elongated walls 500 extending vertically through layers 400 and 401. Additional hardmask material 402 has been formed there-atop as shown in FIG. 12.

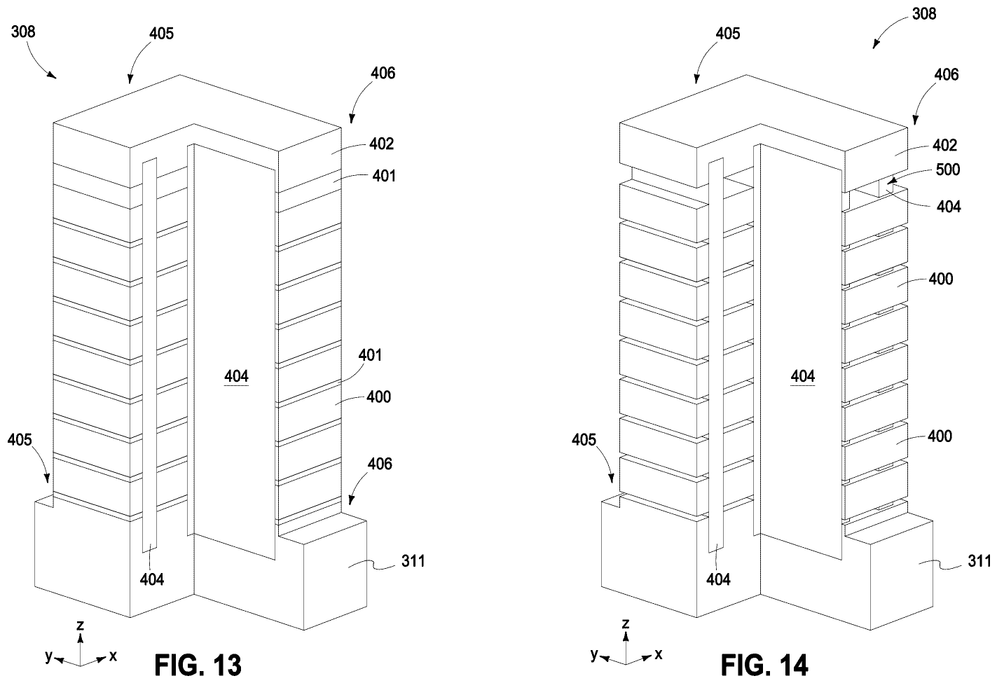

FIG. 13 shows formation of trenches 405 horizontally-elongated in x on what will be the wordline side and trenches 406 horizontally-elongated in x on what will be the capacitor side. FIG. 14 shows etching of silicon-germanium material 401 (no longer shown) selectively relative to silicon-material layers 400.

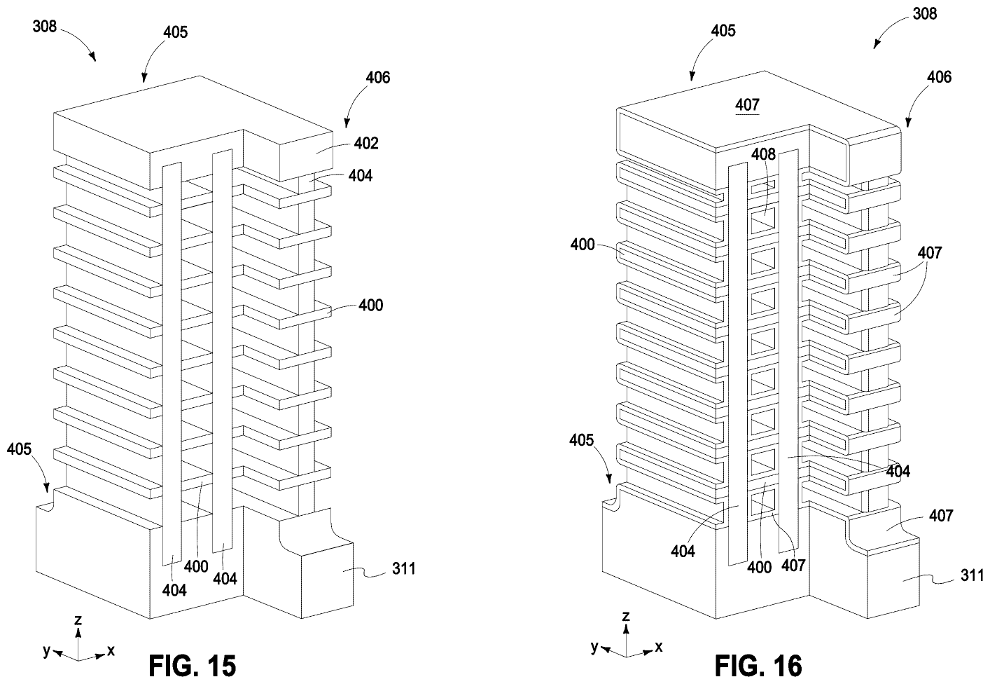

Referring to FIG. 15, silicon-material layers 400 have been first vertically thinned to be at least 2 times as vertically thick as vertical thickness of silicon-material layers 400 in the finished construction (e.g., etched selectively relative to carbon 404 and hardmask 402; e.g., to be at least 2 times as vertically thick as final vertical thickness of components 26, 28, 23, and 60 in the described example structure embodiments). Reference to “first” in this context is sequential relative to “second” and “third” vertical-thinning as referred to below and does not preclude vertical thinning as having occurred before the stated “first” vertical thinning nor preclude vertical thinning occurring between the first and second and the second and the third. Regardless and in one such embodiment, silicon-material layers 400 immediately-after the first thinning are at least 3 times as vertically thick, and in one such embodiment about 4 times as vertically thick, as vertical thickness of silicon-material layers 400 in the finished construction. FIG. 16 shows formation of a thin liner of silicon nitride 407 to leave void spaces 408 as shown.

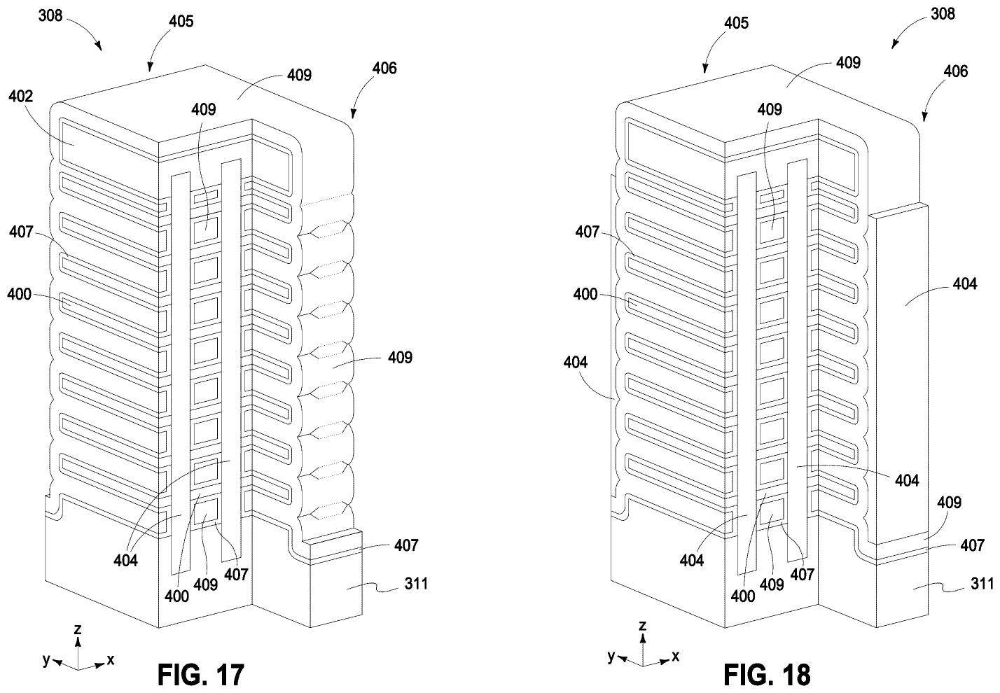

FIG. 17 shows formation of silicon dioxide 409 that fills void spaces 408. FIG. 18 shows formation of more carbon 404 within trenches 405 and 406 followed by vertical recessing thereof.

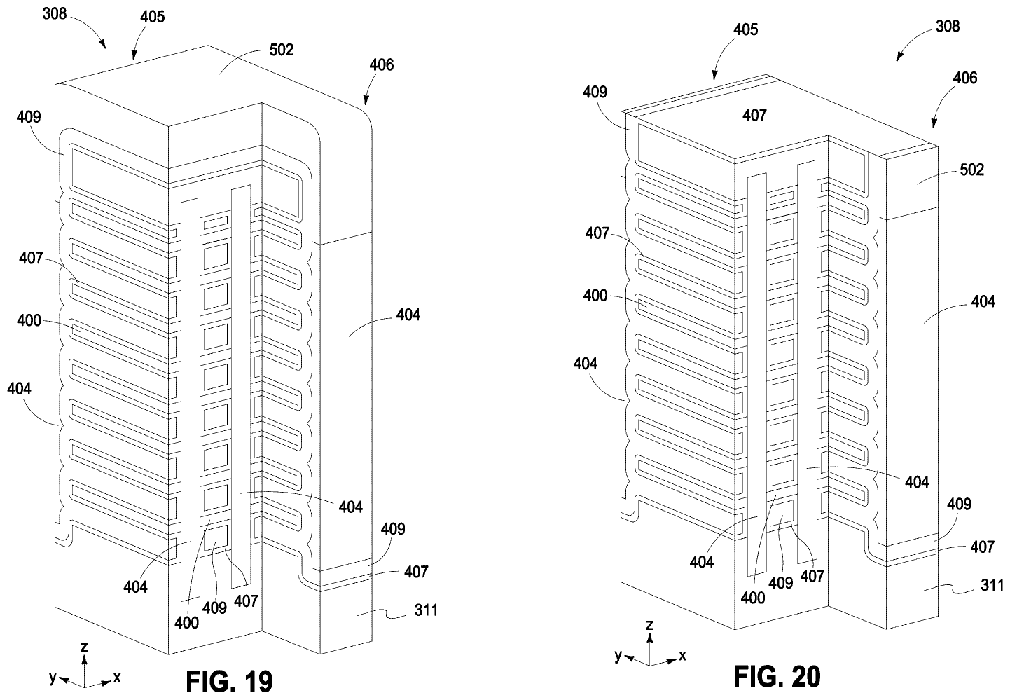

FIG. 19 shows formation of polysilicon masking material 502. FIG. 20 shows removal of a portion thereof to expose silicon nitride 407.

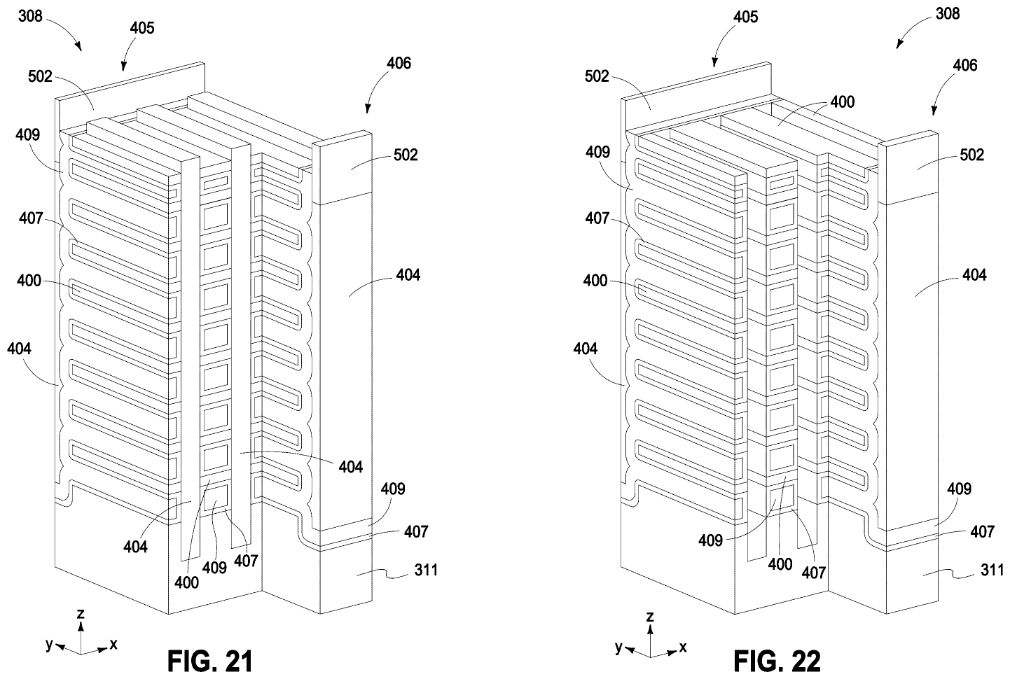

FIG. 21 shows removal of some silicon nitride 407 and more silicon dioxide 409 and exposing carbon 404. FIG. 22 shows removal of carbon 404 (no longer shown), for example by oxygen stripping process.

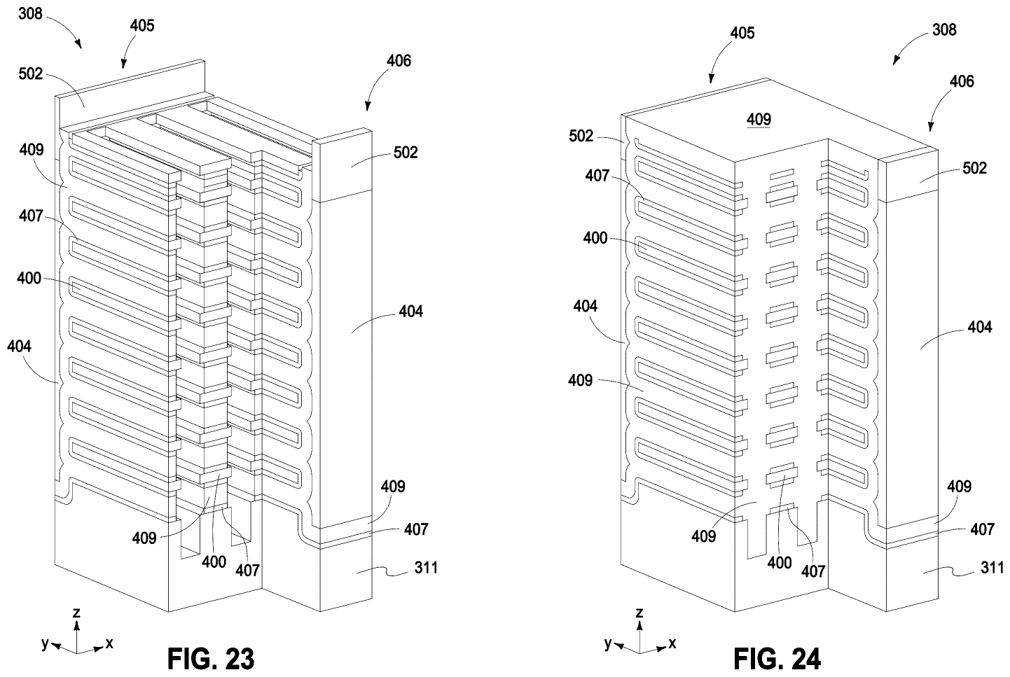

FIG. 23 shows removal of some of silicon nitride 407 to produce the depicted construction (e.g., to remove the vertically-elongated portions thereof). FIG. 24 shows filling of the depicted remaining volumes of trenches 403 with silicon dioxide 409.

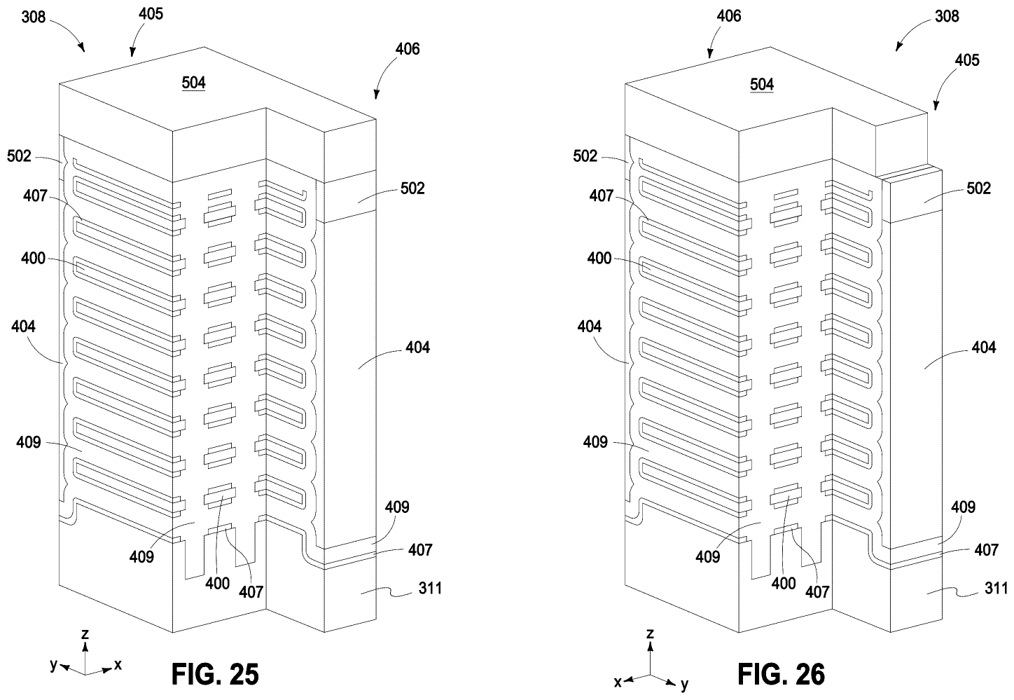

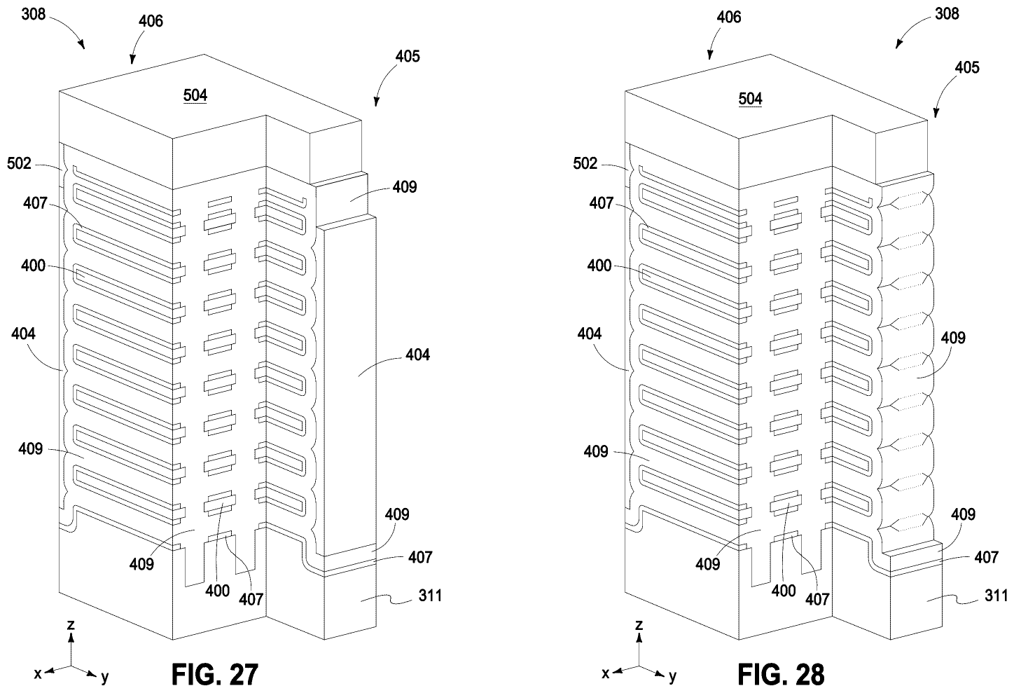

FIG. 25 shows formation of silicon oxycarbide hardmask material 504 and FIG. 26 shows patterning thereof to open such on the wordline side. Note that FIG. 26, as well as FIGS. 27-38, have been rotated relative to FIGS. 11-25, now showing construction 308 from the wordline side as opposed to the capacitor side.

FIG. 27 shows removal of polysilicon masking material 502. FIG. 28 shows stripping of carbon 404 from wordline-side trenches 405.

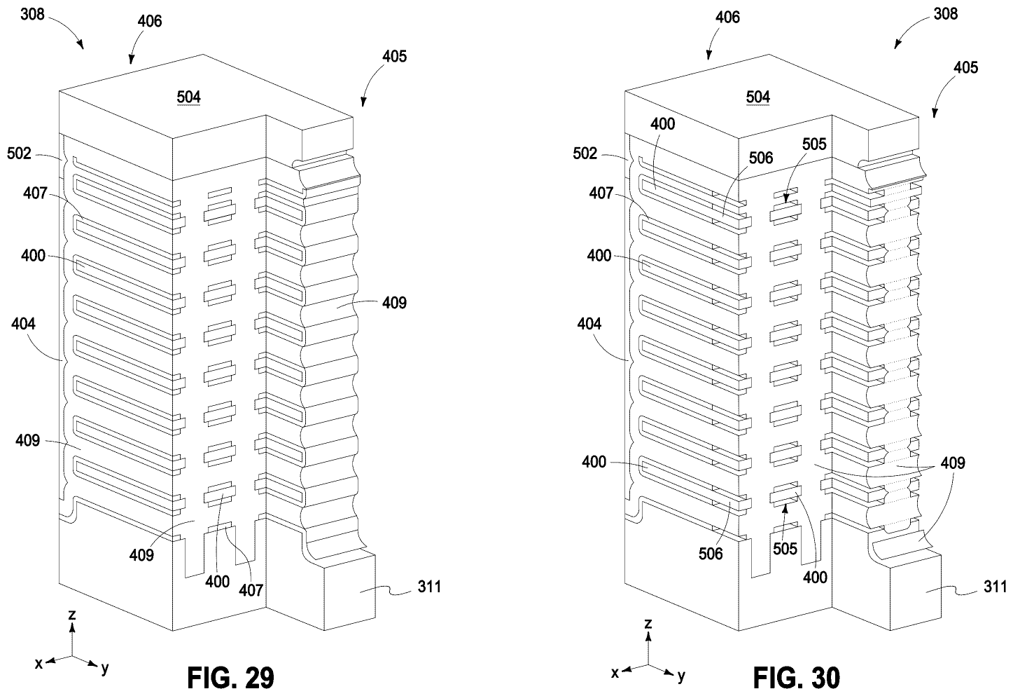

FIG. 29 shows lateral etching of silicon dioxide 409 and FIG. 30 shows lateral recessing of some of silicon nitride 407. Such thereby forms cavities 505 (i.e., an individual cavity 505 including the combination of void space that is both directly above and directly below individual silicon-material layers 400) in a surrounding material (e.g., silicon dioxide 409). Those depicted parts of silicon-material layers 400 that are within cavities 505 may be considered as first-end portions 506 of silicon-material layers 400. In one embodiment, the immediately-surrounding material 409 at least predominantly (i.e., more than 50% up to and including 100% by volume) comprises silicon dioxide.

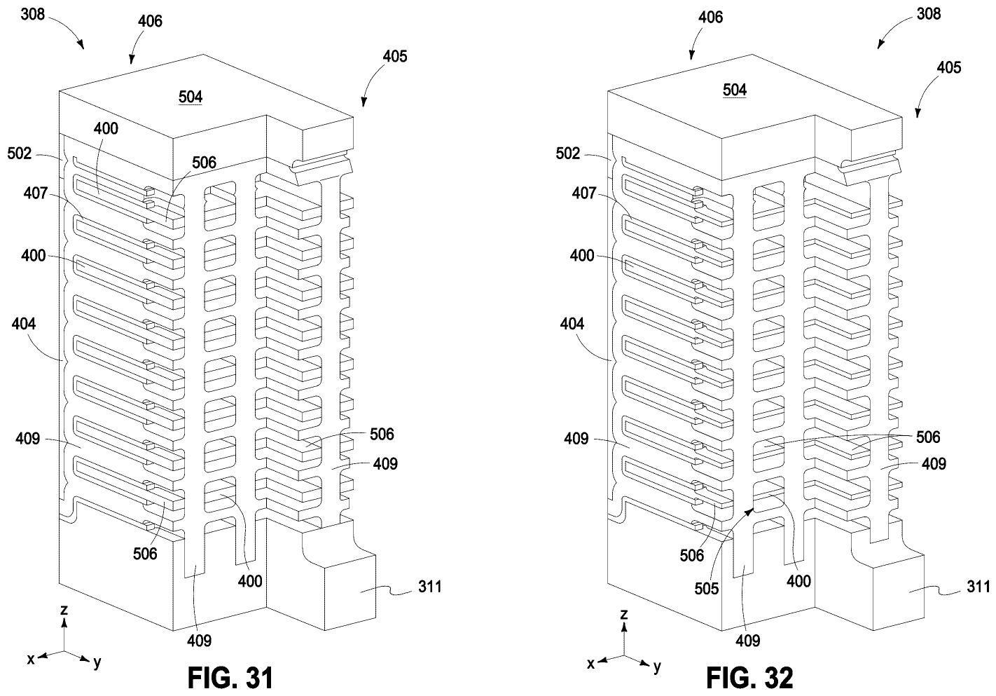

FIG. 31 shows etching of surrounding material 409 to enlarge cavities 505. Ideally, such etching leaves silicon dioxide 409 laterally against outside edges of first-end portions 506 of silicon-material layers 400 (as shown), thereby laterally supporting same. FIG. 32 shows second vertically thinning of silicon-material layers 400 within cavities 505 at their first-end portions 506. Such second vertically thinning is to less than 2 times as vertically thick as the vertical thickness of silicon-material layers 400 in the finished construction.

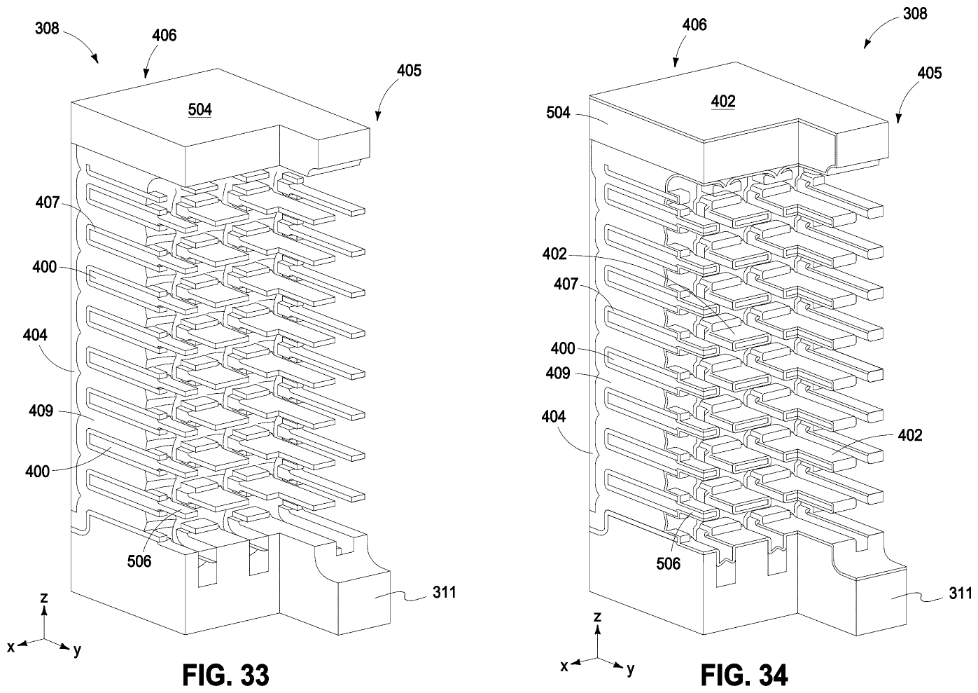

FIG. 33 shows more removal of silicon dioxide 409 (e.g., effectively removing what were cavities 505 that are now no longer shown). FIG. 34 shows formation of a liner of silicon oxycarbide 402.

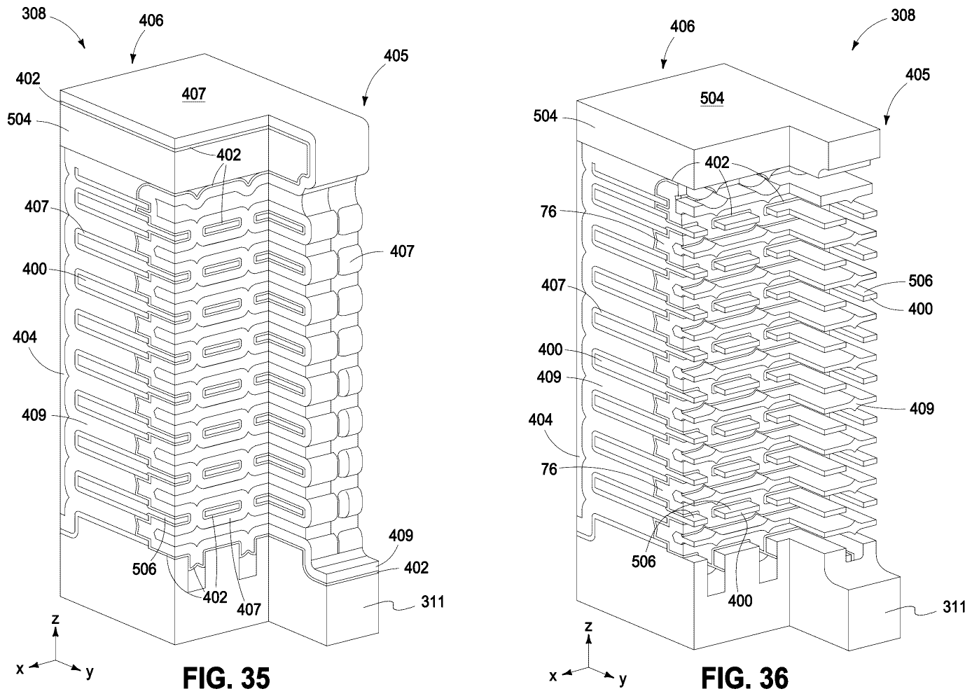

FIG. 35 shows formation of silicon nitride 407, with FIG. 36 showing lateral recessing thereof and thereby in one example forming Y-like shaped insulative structures 76. Silicon oxycarbide liner 402 has subsequently been removed therefrom (e.g., by oxidizing such to SiO₂ and then removing such SiO₂) to expose silicon material 400.

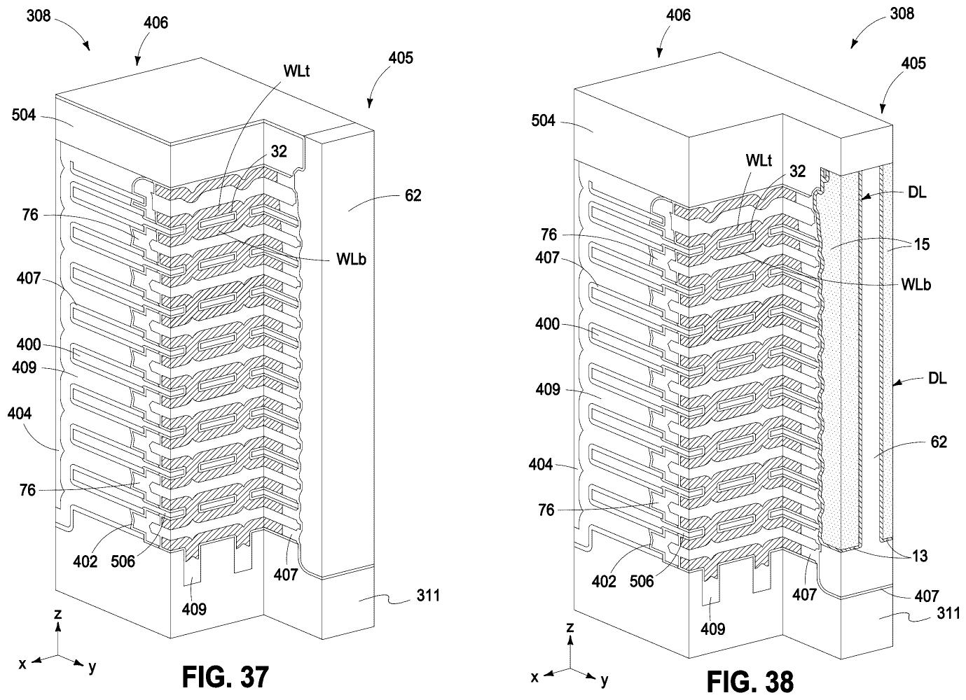

FIG. 37 shows formation of suitable gate insulator 32, then conductive material followed by lateral recessing thereof to form wordlines WLt and WLb, followed by forming more silicon nitride 407 and silicon dioxide 62. FIG. 38 shows formation of digitlines DL. Suitable doping of regions of silicon material 400 could occur where desired to achieve desired conductivity degree and type. Hardmask material 402 has thereafter been deposited to largely protect the wordline side from processing associated with the capacitor side.

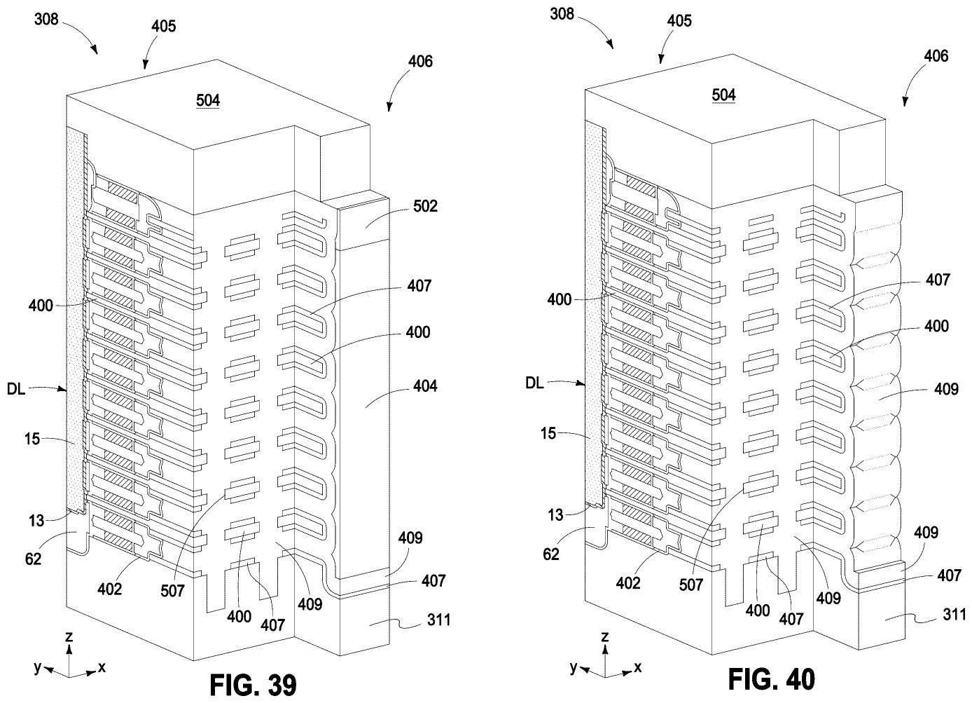

FIG. 39, again now looking from the capacitor side, shows hardmask material 504 as having been opened over capacitor-side trenches 406 and silicon dioxide 409 has been etched to expose carbon 404 therein. FIG. 40 shows removal polysilicon 502 and of carbon 404 from capacitor-side trenches 406 (such carbon 404 and polysilicon 502 thereby no longer being shown).

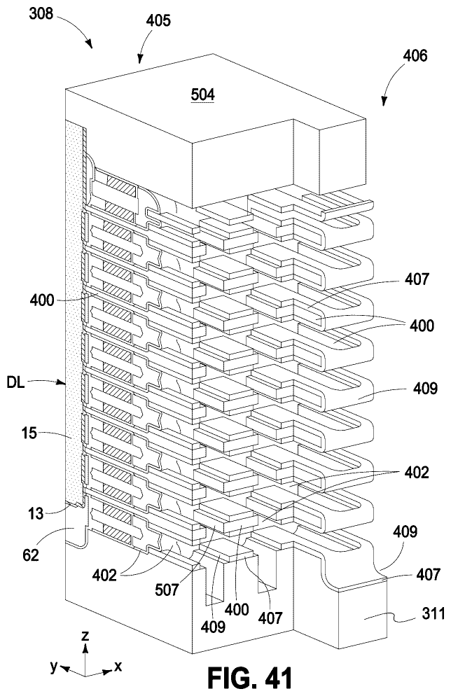

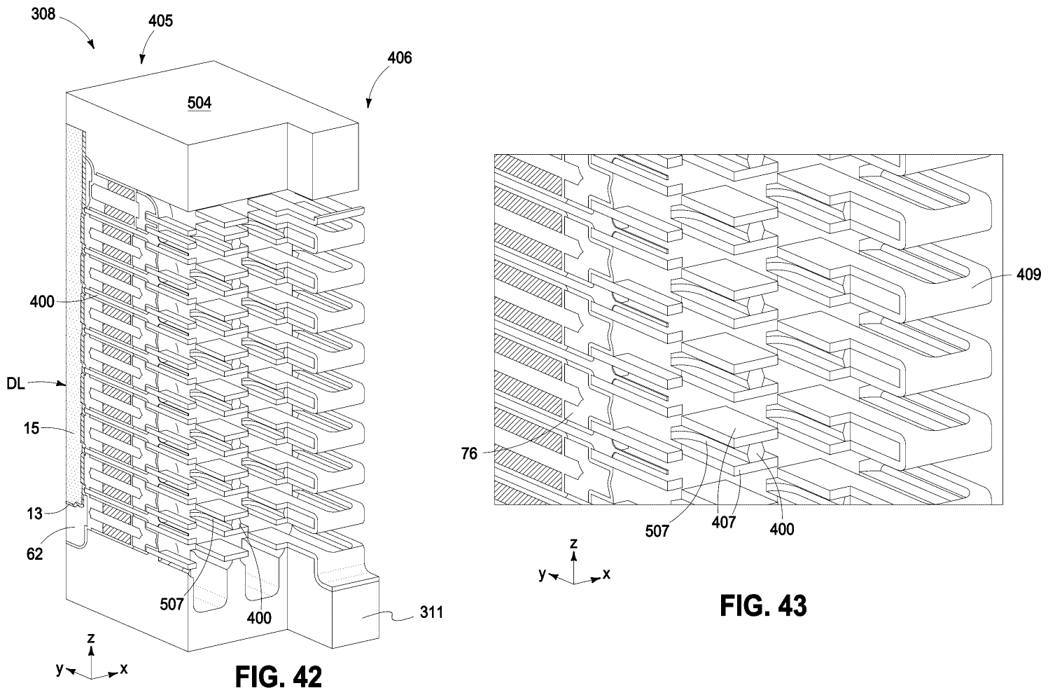

FIG. 41 shows recessing of silicon dioxide 409 stopping on silicon oxycarbide 402. FIGS. 42 and 43 show laterally thinning of second-end portions 507 of silicon-material layers 400, with second-end portions 507 being horizontally opposite first-end portions 506 of FIG. 31.

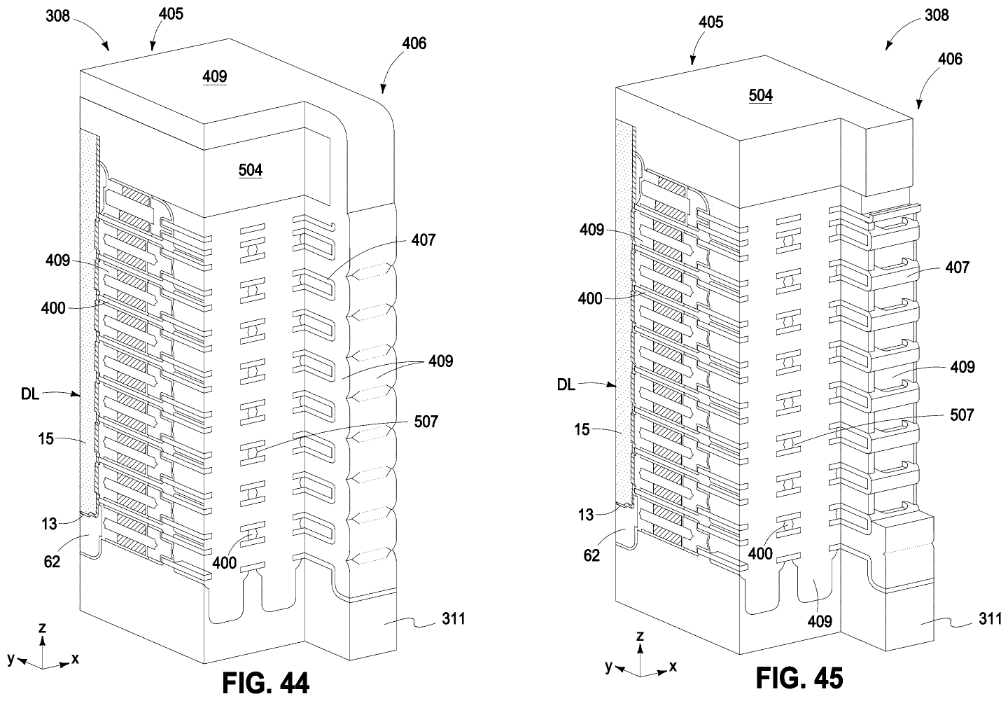

FIG. 44 shows formation of more silicon dioxide 409 and FIG. 45 shows lateral recessing thereof to expose silicon nitride 407.

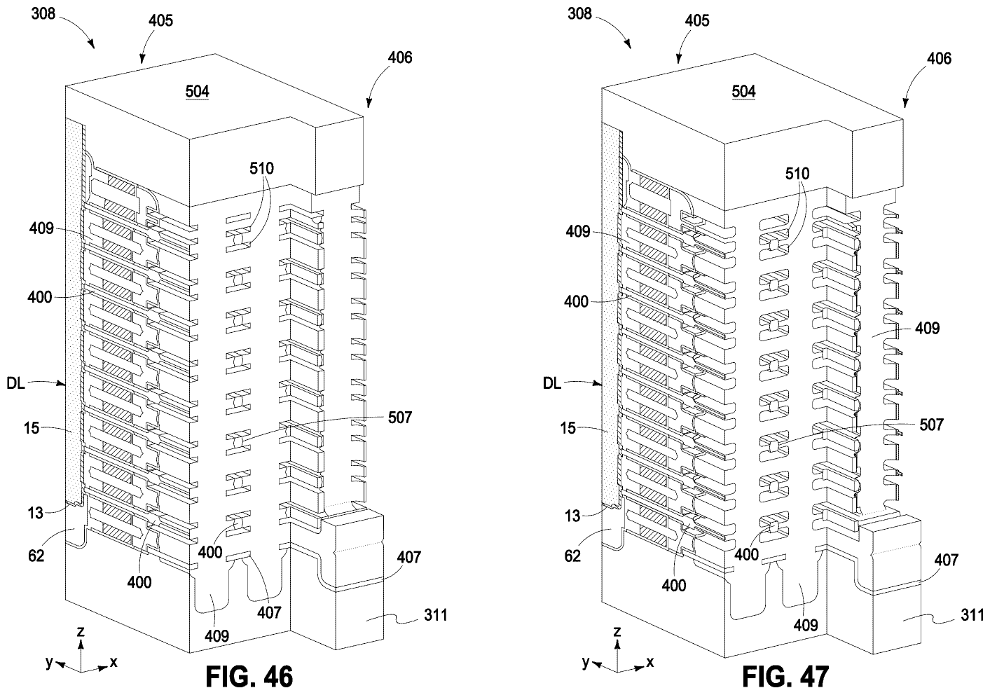

FIG. 46 shows removal of the exposed silicon nitride 407 creating void space 510 above and below second-end portions 507. FIG. 47 shows etching of silicon dioxide 409 to enlarge such void spaces 510.

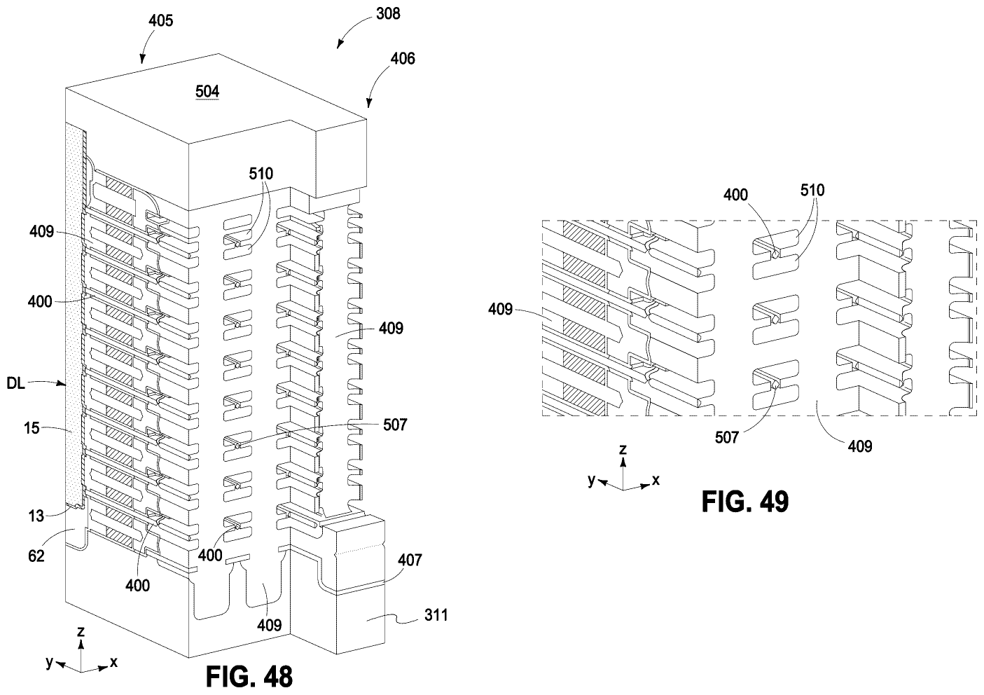

FIGS. 48 and 49 show third-vertically thinning silicon-material layers 400 at their second-end portions 507 (e.g., by isotropic etching). In one such example and as shown, such forms second-end portions 507 of silicon-material layers 400 to be of a diamond-like shape in a vertical cross-section (e.g., that of FIGS. 8, 9, 48, and 49) (e.g., along direction x).

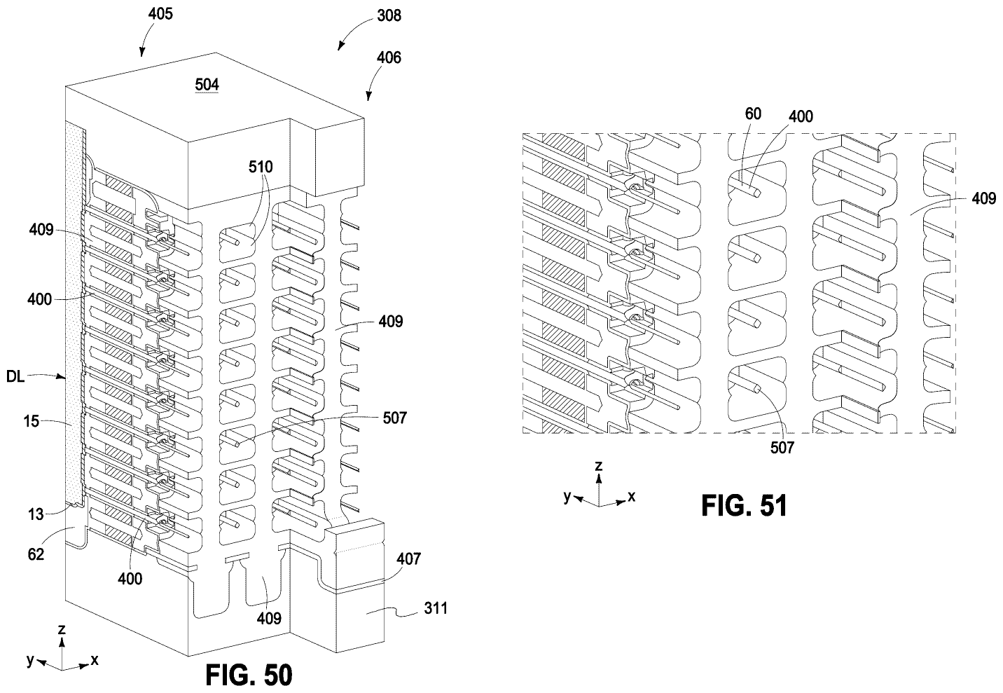

FIGS. 50 and 51 show subsequent further etching of silicon dioxide 409. Conductive doping of silicon 400/mid-portion material 60 may be conducted, for example, after the processing shown by FIGS. 50 and 51, as may formation of silicide 89 (not shown in FIGS. 50 and 51; e.g., by elemental metal deposition onto silicon 400 followed by anneal) as shown in FIGS. 7 and 10. Such silicide might also be formed, for example as described below. All the above processing shown and described relative to FIGS. 11-51 is but one example method of forming such a described construction.

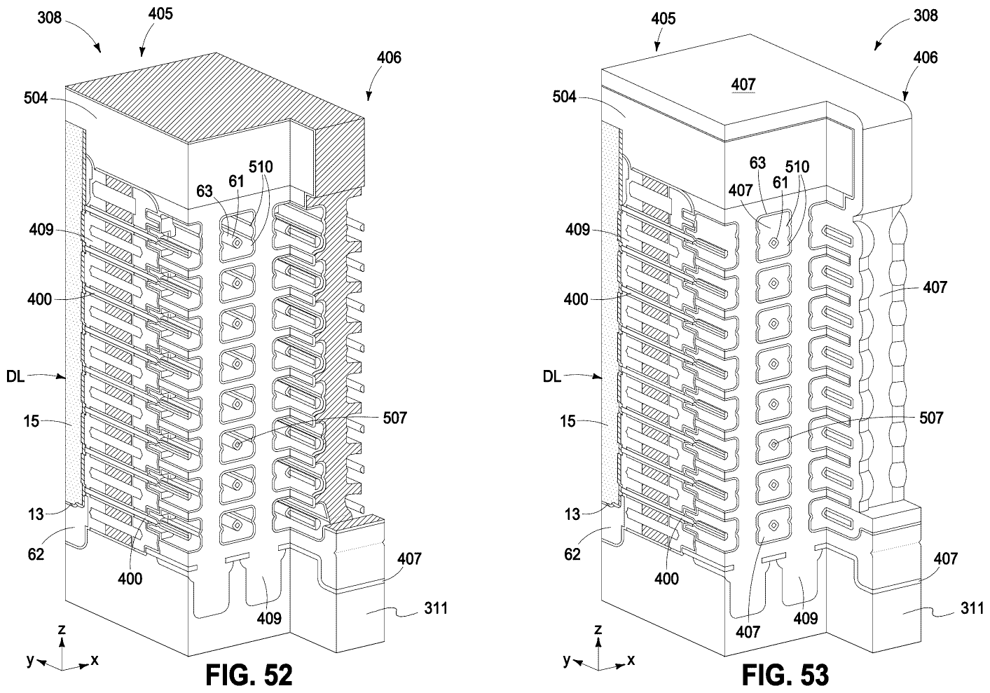

FIG. 52 shows conductive material (e.g., TiN) as having been deposited and thereby forming inner annulus 61 directly electrically coupled with mid-portion material 60 and outer annulus 63 that is directly electrically coupled with inner annulus 61, with outer annulus 63 being about inner annulus 61 in the depicted vertical cross-section of FIGS. 7 and 52. In one embodiment, mid-portion material 60 at least predominantly (more than 50% up to and including 100%) comprises silicon, with the forming of inner and outer annuli 61, 63 comprising forming conductive metal-material directly against the silicon, plus annealing such conductive metal-material and silicon to form a conductive metal silicide (e.g., 89 in FIGS. 7 and 10) directly against the silicon. Such metal silicide may also form laterally aside and directly against the silicon on end 66 (e.g., 89 in FIGS. 7 and 10). FIG. 53 shows filling of remaining void space between annuli 61 and 63 with sacrificial silicon nitride 407.

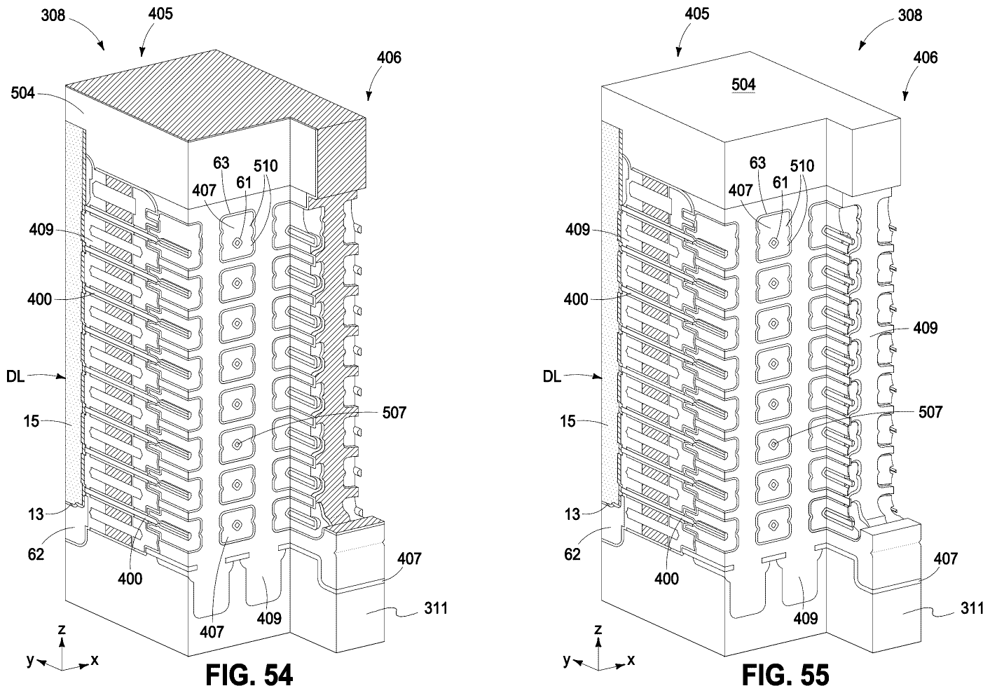

FIG. 54 shows recessing silicon nitride 407 to expose inner and outer annuli 61 and 63, respectively. FIG. 55 shows removing some of the material of inner and outer annuli 61, 63 in trenches 406 to remove such from there-connecting (still connected on the back side).

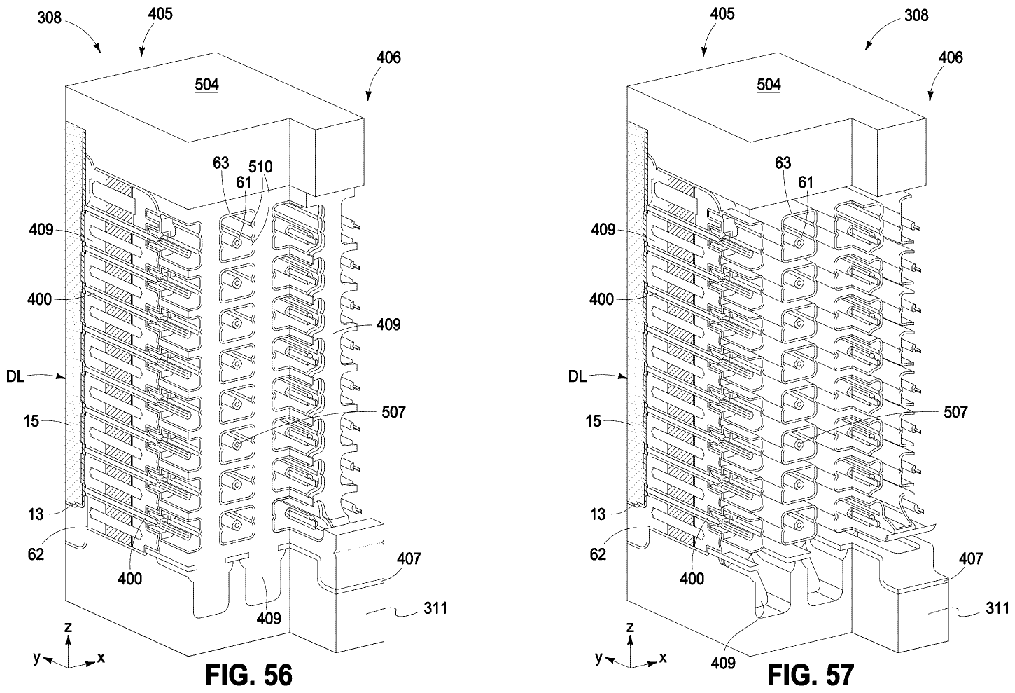

FIG. 56 shows removal of silicon nitride 407 that was radially internally within the previous void space. FIG. 57 shows silicon dioxide 409 as having been removed sufficiently to expose outer surfaces of outer annulus 63.

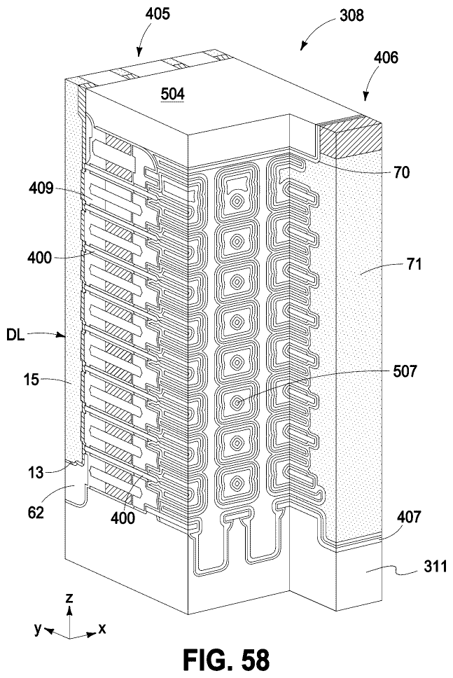

FIGS. 58 along with FIGS. 8 and 9 show subsequent processing wherein capacitor insulator 36 has been formed to comprise first intervening ring 73 about inner annulus 61 between inner annulus 61 and inner ring 68, second intervening ring 74 about inner ring 68 between inner ring 68 and outer annulus 63, and third intervening ring 75 about outer annulus 63 between outer annulus 63 and outer portion 72. Subsequently, common electrode 34 has been formed.

Any other attribute(s) or aspect(s) as shown and/or described herein with respect to other embodiments may be used.

Example embodiments as shown and described herein may provide good memory cell capacitance, more consistent distance between transistor and capacitor, and minimize memory cell-to-memory cell disturb.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, memory circuitry comprises vertically-stacked memory cells individually comprising a horizontal transistor and a capacitor electrically coupled therewith. The capacitor and horizontal transistor are horizontally spaced relative one another along an axis. The capacitor comprises a storage-node electrode, a common electrode that is common to a plurality of the capacitors of the memory cells, and a capacitor insulator between the storage-node and common electrodes. The storage-node electrode comprises a mid-portion on and about the axis. An inner annulus is directly electrically coupled with the mid-portion. The inner annulus is about the mid-portion in a vertical cross-section that is horizontally-elongated orthogonal to the axis. An outer annulus is directly electrically coupled with the inner annulus. The outer annulus is about the inner annulus in the vertical cross-section. The common electrode in the vertical cross-section comprises an inner ring about the inner annulus and an outer portion about the inner ring. The capacitor insulator in the vertical cross-section comprises a first intervening ring about the inner annulus between the inner annulus and the inner ring. A second intervening ring is about the inner ring between the inner ring and the outer annulus. A third intervening ring is about the outer annuus between the outer annulus and the outer portion. The third intervening ring comprises a pair of laterally-opposing radial projections that are individually horizontally aside and point radially inward toward the mid-portion.

In some embodiments, memory circuitry comprises vertically-stacked memory cells individually comprising a horizontal transistor and a capacitor electrically coupled therewith. The capacitor and horizontal transistor are horizontally spaced relative one another along an axis. An insulative structure is vertically between immediately-vertically-adjacent of the memory cells. The insulative structure is of a sideways Y-like shape in a vertical cross-section that is through and horizontally-elongated along the axis. In the vertical cross-section, the insulative structure comprises a horizontal stem and a pair of vertically-spaced and parallel arms that are contiguous with and project horizontally relative to the horizontal stem.

In some embodiments, memory circuitry comprises vertically-stacked memory cells individually comprising a horizontal transistor and a capacitor electrically coupled therewith. The capacitor and horizontal transistor are horizontally spaced relative one another along an axis. The capacitor comprises a storage-node electrode, a common electrode that is common to a plurality of the capacitors of the memory cells, and a capacitor insulator between the storage-node and common electrodes. The storage-node electrode comprises a mid-portion on and about the axis. An upper sideways container is directly electrically coupled with and directly above the mid-portion. The upper sideways container faces horizontally away from the horizontal transistor in a vertical cross-section that is through and horizontally-elongated along the axis. A lower sideways container is directly electrically coupled with and directly below the mid-portion. The lower sideways container faces horizontally away from the horizontal transistor in the vertical cross-section. In the vertical cross-section, each of the upper and lower sideways containers comprises a horizontally-elongated vertically-widest portion and a horizontally-elongated vertically-narrowest portion that are directly against the mid-portion.

In some embodiments, memory circuitry comprises vertically-stacked memory cells individually comprising a horizontal transistor and a capacitor electrically coupled therewith. The capacitor and horizontal transistor are horizontally spaced relative one another along an axis. The capacitor comprises a storage-node electrode, a common electrode that is common to a plurality of the capacitors of the memory cells, and a capacitor insulator between the storage-node and common electrodes. In a vertical cross-section that is horizontally-elongated orthogonal to the axis, the storage-node electrode comprises a radially-inner portion that is spaced from a radially-outer portion at least by the capacitor insulator and the common electrode. The radially-inner portion is of a diamond-like shape in the vertical cross-section.

In some embodiments, a method used in forming memory circuitry comprises forming vertically-alternating layers comprising silicon material and silicon-germanium material directly above a substrate. The silicon-material layers comprise part of horizontal transistors and capacitors in a finished construction of the memory circuitry. Individual memory cells of the memory circuitry comprise one of the horizontal transistors and one of the capacitors electrically coupled therewith. The layers comprising the silicon-germanium material are removed. After the removing, the silicon-material layers are first vertically thinned to be at least 2 times as vertically thick as vertical thickness of the silicon-material layers in the finished construction. Cavities are formed in a surrounding material. First-end portions of the silicon-material layers are within the cavities. Second vertically thinning of the silicon-material layers occurs within the cavities at their first-end portions. The second vertically thinning is to less than 2 times as vertically thick as the vertical thickness of the silicon-material layers in the finished construction. Second-end portions of the silicon-material layers that are horizontally opposite the first-end portions are laterally thinned. After the laterally thinning, third vertically thinning of the silicon-material layers occurs at their second-end portions.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. Memory circuitry comprising:
vertically-stacked memory cells individually comprising a horizontal transistor and a capacitor electrically coupled therewith; the capacitor and horizontal transistor being horizontally spaced relative one another along an axis; the capacitor comprising a storage-node electrode, a common electrode that is common to a plurality of the capacitors of the memory cells, and a capacitor insulator between the storage-node and common electrodes;
the storage-node electrode comprising:
a mid-portion on and about the axis;
an inner annulus directly electrically coupled with the mid-portion, the inner annulus being about the mid-portion in a vertical cross-section that is horizontally-elongated orthogonal to the axis; and
an outer annulus directly electrically coupled with the inner annulus, the outer annulus being about the inner annulus in the vertical cross-section;
the common electrode in the vertical cross-section comprising an inner ring about the inner annulus and an outer portion about the inner ring; and
the capacitor insulator in the vertical cross-section comprising:
a first intervening ring about the inner annulus between the inner annulus and the inner ring;
a second intervening ring about the inner ring between the inner ring and the outer annulus; and
a third intervening ring about the outer annuus between the outer annulus and the outer portion, the third intervening ring comprising a pair of laterally-opposing radial projections that are individually horizontally aside and point radially inward toward the mid-portion.

2. The memory circuitry of claim 1 wherein, in the vertical cross-section, the outer annulus has a pair of laterally-opposing radial projections that are individually horizontally aside and point radially inward toward the mid-portion.

3. The memory circuitry of claim 1 wherein, in the vertical cross-section, the second intervening ring has a pair of laterally-opposing radial projections that are individually horizontally aside and point radially inward toward the mid-portion.

4. The memory circuitry of claim 1 wherein, in the vertical cross-section,
the outer annulus has a pair of laterally-opposing radial projections that are individually horizontally aside and point radially inward toward the mid-portion; and
the second intervening ring has a pair of laterally-opposing radial projections that are individually horizontally aside and point radially inward toward the mid-portion.

5. The memory circuitry of claim 1 wherein the mid-portion comprises a conductive metal silicide there-atop and there-below and that are respectively directly against the inner annulus.

6. The memory circuitry of claim 5 wherein the mid-portion has an end on the axis, the silicide being laterally over and aside the mid-portion end.

7. The memory circuitry of claim 1 wherein,
the mid-portion has an end on the axis;
the storage-node electrode comprises a connecting portion laterally over and aside the end in a vertical cross-section that is through and horizontally-elongated along the axis, the connecting portion being contiguous with the inner annulus; and
the capacitor insulator being laterally between the connecting portion and the common electrode.

8. The memory circuitry of claim 1 comprising an insulative structure vertically between immediately-vertically-adjacent of the memory cells; the insulative structure being of a sideways Y-like shape in a vertical cross-section that is through and horizontally-elongated along the axis; in the vertical cross-section that is through and horizontally-elongated along the axis, the insulative structure comprising a horizontal stem and a pair of vertically-spaced and parallel arms that are contiguous with and project horizontally relative to the horizontal stem.

9. The memory circuitry of claim 1 wherein the storage-node electrode comprises:
an upper sideways container directly electrically coupled with and directly above the mid-portion, the upper sideways container facing horizontally away from the horizontal transistor in a vertical cross-section that is through and horizontally-elongated along the axis;
a lower sideways container directly electrically coupled with and directly below the mid-portion, the lower sideways container facing horizontally away from the horizontal transistor in the vertical cross-section that is through and horizontally-elongated along the axis;
the inner and outer annuli comprising part of each of the upper and lower sideways containers; and
in the vertical cross-section that is through and horizontally-elongated along the axis, each of the upper and lower sideways containers comprising a horizontally-elongated vertically-widest portion and a horizontally-elongated vertically-narrowest portion that are directly against the mid-portion.

10. The memory circuitry of claim 1 wherein the mid-portion is of a diamond-like shape in the vertical cross-section.

11. The memory circuitry of claim 1 wherein,
the storage-node electrode comprises:
an upper sideways container directly electrically coupled with and directly above the mid-portion, the upper sideways container facing horizontally away from the horizontal transistor in a vertical cross-section that is through and horizontally-elongated along the axis;
a lower sideways container directly electrically coupled with and directly below the mid-portion, the lower sideways container facing horizontally away from the horizontal transistor in the vertical cross-section that is through and horizontally-elongated along the axis;
the inner and outer annuli comprising part of each of the upper and lower sideways containers; and
in the vertical cross-section that is through and horizontally-elongated along the axis, each of the upper and lower sideways containers comprising a horizontally-elongated vertically-widest portion and a horizontally-elongated vertically-narrowest portion that are directly against the mid-portion;
the mid-portion is of a diamond-like shape in the vertical cross-section that is horizontally-elongated orthogonal to the axis; and
further comprising:
an insulative structure vertically between immediately-vertically-adjacent of the memory cells; the insulative structure being of a sideways Y-like shape in the vertical cross-section that is through and horizontally-elongated along the axis; in the vertical cross-section that is through and horizontally-elongated along the axis, the insulative structure comprising a horizontal stem and a pair of vertically-spaced and parallel arms that are contiguous with and project horizontally relative to the horizontal stem.

12. Memory circuitry comprising:
vertically-stacked memory cells individually comprising a horizontal transistor and a capacitor electrically coupled therewith, the capacitor and horizontal transistor being horizontally spaced relative one another along an axis; and
an insulative structure vertically between immediately-vertically-adjacent of the memory cells; the insulative structure being of a sideways Y-like shape in a vertical cross-section that is through and horizontally-elongated along the axis; in the vertical cross-section, the insulative structure comprising a horizontal stem and a pair of vertically-spaced and parallel arms that are contiguous with and project horizontally relative to the horizontal stem.

13. The memory circuitry of claim 12 wherein, in the vertical cross-section,
the horizontal transistor comprises a top gate and a bottom gate, one of the arms being vertically aligned with the bottom gate of an upper of the immediately-vertically-adjacent memory cells; and
the other of the arms being vertically aligned with the top gate of a lower of the immediately-vertically-adjacent memory cells.

14. The memory circuitry of claim 12 wherein vertical thickness of the horizontal stem is greater than vertical thickness of each of the arms.

15. The memory circuitry of claim 12 wherein the capacitor comprises a storage-node electrode, a common electrode that is common to a plurality of the capacitors of the memory cells, and a capacitor insulator between the storage-node and common electrodes, the storage-node electrode comprising:
a mid-portion on and about the axis;
an upper sideways container directly electrically coupled with and directly above the mid-portion, the upper sideways container facing horizontally away from the horizontal transistor in the vertical cross-section;
a lower sideways container directly electrically coupled with and directly below the mid-portion, the lower sideways container facing horizontally away from the horizontal transistor in the vertical cross-section; and
in the vertical cross-section that is through and horizontally-elongated along the axis, each of the upper and lower sideways containers comprising a horizontally-elongated vertically-widest portion and a horizontally-elongated vertically-narrowest portion that are directly against the mid-portion.

16. The memory circuitry of claim 12 wherein the mid-portion is of a diamond-like shape in a vertical cross-section that is horizontally-elongated orthogonal to the axis.

17. The memory circuitry of claim 12 wherein,
the capacitor comprises a storage-node electrode, a common electrode that is common to a plurality of the capacitors of the memory cells, and a capacitor insulator between the storage-node and common electrodes, the storage-node electrode comprising:
a mid-portion on and about the axis;
an upper sideways container directly electrically coupled with and directly above the mid-portion, the upper sideways container facing horizontally away from the horizontal transistor in the vertical cross-section;
a lower sideways container directly electrically coupled with and directly below the mid-portion, the lower sideways container facing horizontally away from the horizontal transistor in the vertical cross-section; and
in the vertical cross-section that is through and horizontally-elongated along the axis, each of the upper and lower sideways containers comprising a horizontally-elongated vertically-widest portion and a horizontally-elongated vertically-narrowest portion that are directly against the mid-portion; and
the mid-portion is of a diamond-like shape in a vertical cross-section that is horizontally-elongated orthogonal to the axis.

18. Memory circuitry comprising:
vertically-stacked memory cells individually comprising a horizontal transistor and a capacitor electrically coupled therewith; the capacitor and horizontal transistor being horizontally spaced relative one another along an axis; the capacitor comprising a storage-node electrode, a common electrode that is common to a plurality of the capacitors of the memory cells, and a capacitor insulator between the storage-node and common electrodes; and
the storage-node electrode comprising:
a mid-portion on and about the axis;
an upper sideways container directly electrically coupled with and directly above the mid-portion, the upper sideways container facing horizontally away from the horizontal transistor in a vertical cross-section that is through and horizontally-elongated along the axis;
a lower sideways container directly electrically coupled with and directly below the mid-portion, the lower sideways container facing horizontally away from the horizontal transistor in the vertical cross-section; and
in the vertical cross-section, each of the upper and lower sideways containers comprising a horizontally-elongated vertically-widest portion and a horizontally-elongated vertically-narrowest portion that are directly against the mid-portion.

19-21. (canceled)

22. Memory circuitry comprising:
vertically-stacked memory cells individually comprising a horizontal transistor and a capacitor electrically coupled therewith; the capacitor and horizontal transistor being horizontally spaced relative one another along an axis; the capacitor comprising a storage-node electrode, a common electrode that is common to a plurality of the capacitors of the memory cells, and a capacitor insulator between the storage-node and common electrodes; and
in a vertical cross-section that is horizontally-elongated orthogonal to the axis, the storage-node electrode comprising a radially-inner portion that is spaced from a radially-outer portion at least by the capacitor insulator and the common electrode, the radially-inner portion being of a diamond-like shape in the vertical cross-section.

23. (canceled)

24. A method used in forming memory circuitry, comprising:
forming vertically-alternating layers comprising silicon material and silicon-germanium material directly above a substrate, the silicon-material layers comprising part of horizontal transistors and capacitors in a finished construction of the memory circuitry, individual memory cells of the memory circuitry comprising one of the horizontal transistors and one of the capacitors electrically coupled therewith;
removing the layers comprising the silicon-germanium material;
after the removing, first vertically thinning the silicon-material layers to be at least 2 times as vertically thick as vertical thickness of the silicon-material layers in the finished construction;
forming cavities in a surrounding material, first-end portions of the silicon-material layers being within the cavities;
second vertically thinning the silicon-material layers within the cavities at their first-end portions, the second vertically thinning being to less than 2 times as vertically thick as the vertical thickness of the silicon-material layers in the finished construction;
laterally thinning second-end portions of the silicon-material layers that are horizontally opposite the first-end portions; and
after the laterally thinning, third vertically thinning the silicon-material layers at their second-end portions.

25-31. (canceled)
